(19) United States
(12) Patent Application Publication
(10) Pub. No.: US 2011/0191617 A1
(43) Pub. Date: Aug. 4, 2011

(54) APPARATUS FOR CHARGER CIRCUIT IN PORTABLE TERMINAL AND OPERATION METHOD THEREOF

(75) Inventor: Kwon-Chon KWAK, Seoul (KR)

(73) Assignee: SAMSUNG ELECTRONICS CO. LTD., Suwon-si (KR)

(21) Appl. No.: 13/009,144

(22) Filed: Jan. 19, 2011

(30) Foreign Application Priority Data
Jan. 29, 2010 (KR) 10-2010-0008351

(51) Int. Cl. G06F 1/26; G06F 19/00; G01R 31/36; G05B 23/02

(52) U.S. Cl. 713/323; 702/58; 340/3.44

(57) ABSTRACT

An apparatus for a charger circuit in a portable terminal and an operation method thereof are provided. The apparatus includes a charger Integrated Circuit (IC) for, upon detecting an insertion of a charging cable, determining whether a charging error occurs by collecting charging-related information, and for outputting a signal for indicating the occurrence of the charging error, and a Central Processing Unit (CPU) for performing an error control operation upon receiving the signal for indicating the occurrence of the charging error from the charger IC.

### PRIORITY

This application claims the benefit under 35 U.S.C. §119(a) of a Korean patent application filed in the Korean Intellectual Property Office on Jan. 29, 2010 and assigned Serial No. 10-2010-0008351, the entire disclosure of which is hereby incorporated by reference.

### BACKGROUND OF THE INVENTION

1. Field of the Invention

The present invention relates to an apparatus for a charger circuit in a portable terminal and an operation method thereof. More particularly, the present invention relates to an apparatus for detecting an error situation in a charger Integrated Circuit (IC) embedded in the portable terminal and an operation method thereof.

2. Description of the Related Art

Recently, portable terminals such as Personal Digital Assistants (PDAs) and mobile devices use charger Integrated Circuits (ICs) for charging.

An error may occur due to temperature, current, or voltage during a charging operation of the portable terminal. Therefore, the portable terminal should detect the error generated during the charging operation so as to perform an operation for handling the error. However, since a charger IC of the related art is a passive element that supports only charging and auxiliary charging functions, the portable terminal detects the error generated during the charging operation by using a Central Processing Unit (CPU).

FIG. 1 is a block diagram of a portable terminal for a charging operation according to the related art.

Referring to FIG. 1, a portable terminal includes a CPU 100 that periodically monitors state information related to charging of a charger IC 110 through an Inter-Integrated Circuit (I²C) communication channel 120 during a charging operation, and when the charging error occurs, performs an operation for handling the error.

However, when the operation of the CPU 100 is performed during the charging operation, some of the charging current to be supplied to a battery are consumed, which results in deterioration of charging efficiency.

Therefore, a need exists for an apparatus for detecting a charging error in a charger IC embedded in a portable terminal and an operation method thereof.

### SUMMARY OF THE INVENTION

An aspect of the present invention is to address at least the above-mentioned problems and/or disadvantages and to provide at least the advantages described below. Accordingly, an aspect of the present invention is to provide an apparatus for a charger circuit in a portable terminal and an operation method thereof.

Another aspect of the present invention is to provide an apparatus for detecting a charging error in a charger Integrated Circuit (IC) embedded in a portable terminal and an operation method thereof.

Still another aspect of the present invention is to provide an apparatus for a charger circuit for allowing a Central Processing Unit (CPU) to transition to a sleep mode during a charging operation of a portable terminal and an operation method thereof.

In accordance with an aspect of the present invention, an apparatus for a charger circuit in a portable terminal is provided. The apparatus includes a charger IC for, upon detecting insertion of a charging cable, determining whether a charging error occurs by collecting charging-related information, and for outputting a signal for indicating the occurrence of the charging error, and a CPU for performing an error control operation upon receiving the signal for indicating the occurrence of the charging error from the charger IC.

In accordance with another aspect of the present invention, a method of operating a charger circuit in a portable terminal is provided. The method includes detecting insertion of a charging cable, upon detecting the insertion of the charging cable, determining by a charger IC whether a charging error occurs by collecting charging-related information, outputting a signal for indicating the occurrence of the charging error by the charger IC to a CPU, and performing a control operation depending on a charging error by the CPU.

Other aspects, advantages, and salient features of the invention will become apparent to those skilled in the art from the following detailed description, which, taken in conjunction with the annexed drawings, discloses exemplary embodiments of the invention

### BRIEF DESCRIPTION OF THE DRAWINGS

The above and other aspects, features, and advantages of certain exemplary embodiments of the present invention will be more apparent from the following detailed description taken in conjunction with the accompanying drawings, in which:

FIG. 1 is a block diagram of a portable terminal for a charging operation according to the related art;

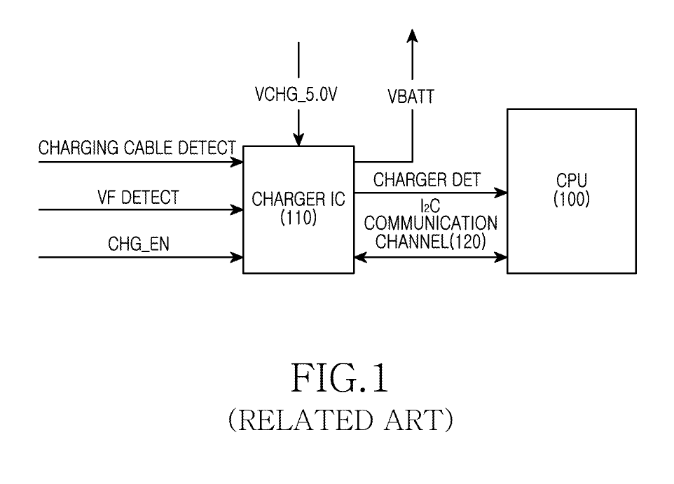

FIG. 2 is a block diagram of a portable terminal according to an exemplary embodiment of the present invention; and

FIG. 3 is a flowchart illustrating a process of detecting a charging error in a portable terminal according to an exemplary embodiment of the present invention.

Throughout the drawings, like reference numerals will be understood to refer to like parts, components and structures.

DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. In addition, the terms and words are defined with consideration of functions in exemplary embodiments of the present invention and may change depending on the intentions or practices of a user and an operator. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

Exemplary embodiments of the present invention described below relate to a technique for detecting a charging error in a charger Integrated Circuit (IC) embedded in a portable terminal.

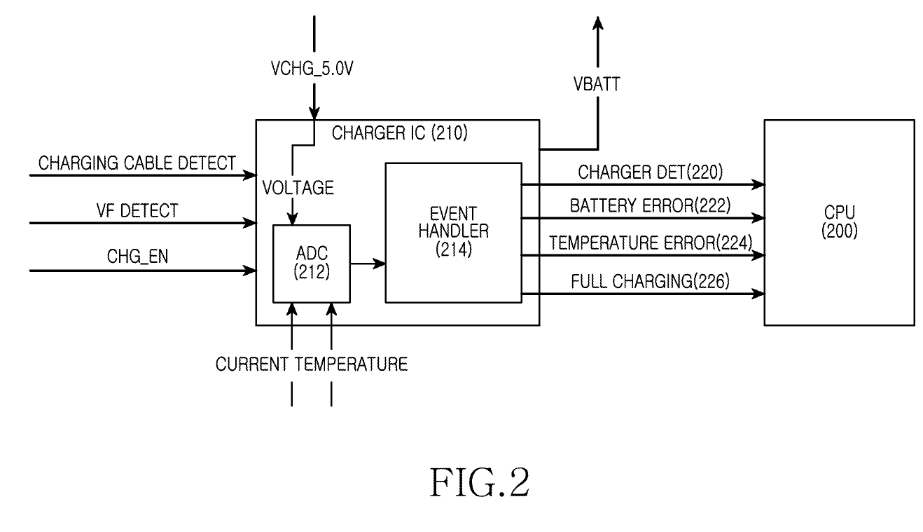

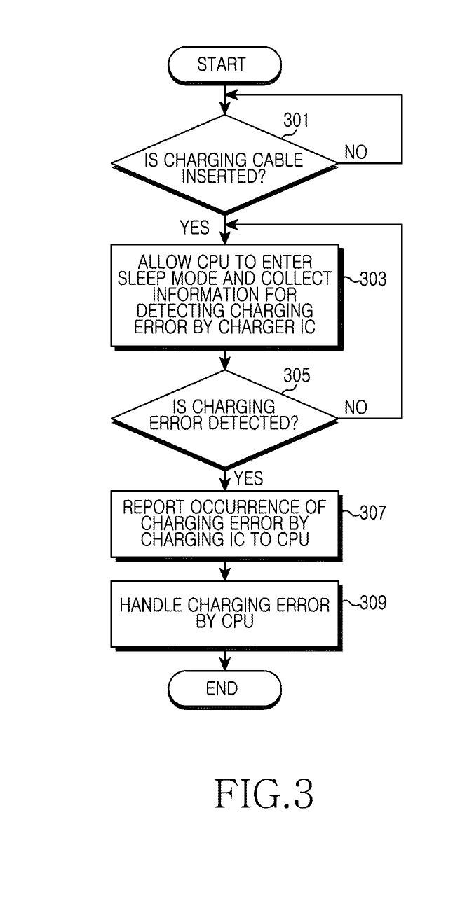

FIGS. 2 and 3, discussed below, and the various exemplary embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly state otherwise. A set is defined as a non-empty set including at least one element.

FIG. 2 is a block diagram of a portable terminal according to an exemplary embodiment of the present invention.

Referring to FIG. 2, a portable terminal includes a Central Processing Unit (CPU) 200 and a charger Integrated Circuit (IC) 210. The charger IC 210 includes an Analog to Digital Converter (ADC) 212 and an event handler 214.

The CPU 200 controls and processes overall operations of the portable terminal. According to an exemplary embodiment of the present invention, the CPU 200 enters a sleep mode in a battery charging process, and when a signal for reporting a charging error is input from the charger IC 210, performs a control operation (e.g., a charging prohibition operation) corresponding to the charging error. Examples of the charging error include a battery error caused by an unauthorized battery or a battery fault, a full charging error, a temperature error, an over voltage error, etc. The control operation caused by the charging error is performed in the same manner as the method of the related art. The CPU 200 may detect a battery charging state according to a charging cable detection signal, i.e., Charger Det, provided from the charger IC 210. Further, the CPU 200 may detect an occurrence of the over voltage error when the charging cable detection signal is not applied. Although it is described herein that a charging cable detection signal transmission line 220, a battery error signal transmission line 222, a temperature error signal transmission line 224, and a full charging error signal transmission line 226 exist between the CPU 200 and the charger IC 210, and whether the battery is charged and whether the over voltage error occurs are determined according to a signal applied to the charging cable detection signal transmission line 220, this is for exemplary purposes only. Thus, the transmission line for the charging cable detection signal and the transmission line for the over voltage error signal may be separately configured.

The charger IC 210 determines whether a charging cable is inserted to the portable terminal, and when the insertion of the charging cable is detected, reports it to the CPU 200, and provides a battery (not shown) with power applied through the charging cable. The charger IC 210 receives a Voltage Feedback (VF) detection signal and a charging enable/disable signal, and measures voltage, current, and temperature by using the ADC 212 according to an exemplary embodiment of the present invention. Thereafter, the charger IC 210 determines whether a charging error occurs by using the event handler 214 based on the provided signal and measured information, and when the charging error occurs, transmits a signal for indicating the occurrence of the charging error to the CPU 200. Herein, the VF detection signal indicates target charging voltage.

That is, the charger IC 210 periodically collects or measures the VF detection signal, the charging enable/disable signal, the voltage, the current, and the temperature, and determines whether the charging error occurs by using the collected or measured information. For example, it is determined whether the temperature measured using the ADC 212 is within a threshold range, whether the current measured using the ADC 212 is less than or equal to threshold current, whether the voltage charged to the battery (not shown) is equal to VF, or whether the charging enable/disable signal indicates that charging is enabled. Herein, the charger IC 210 may detect the occurrence of the charging error when the measured temperature is greater than or equal to 45° C. or less than or equal to −3° C., or when the measured current is greater than or equal to 7V. In this case, the method of detecting the charging error by using the collected or measured information may be the same as the method of the related art.

At the occurrence of the charging error, the charger IC 210 transmits a signal for indicating the occurrence of the charging error to the CPU 200 by using the transmission lines existing between the CPU 200 and the charger IC 210.

FIG. 3 is a flowchart illustrating a process of detecting a charging error in a portable terminal according to an exemplary embodiment of the present invention.

Referring to FIG. 3, a portable terminal detects whether a charging cable is inserted in step 301.

If it is determined in step 301 that the charging cable is inserted, the portable terminal allows the CPU 200 to enter a sleep mode, and collects information for detecting a charging error by using the charger IC 210 in step 303. Herein, examples of the information for detecting the charging error include temperature, current, voltage, and a VF value. In this case, the current and voltage values can be measured by using the ADC 212 included in the charger IC 210.

In step 305, the portable terminal analyzes the collected information to detect the occurrence of the charging error. For example, the portable terminal determines whether the collected temperature is within a threshold range, whether the current is less than or equal to a threshold current, whether the voltage charged to the battery (not shown) is equal to a VF, or whether a charging enable/disable signal indicates that charging is enabled. Herein, the portable terminal can detect the occurrence of the charging error when the measured temperature is greater than or equal to 45° C. or less than or equal to −3° C., or when the collected current is greater than or equal to 7V. In this case, the method of detecting the charging error by using the collected information may be the same as the method of the related art.

If it is determined in step 305 that the charging error does not occur, returning to step 303, the subsequent steps are repeated. In contrast, if it is determined in step 305 that the charging error occurs, the portable terminal transmits a signal for reporting the occurrence of the charging error to the CPU 200 by using the charger IC 210 in step 307. In this case, the CPU 200 is released from the sleep mode.

In step 309, the portable terminal handles the charging error by using the CPU 200. For example, the portable terminal can perform a charging prohibition operation when the charging error occurs.

Thereafter, the procedure of FIG. 3 ends.

According to exemplary embodiments of the present invention, a charger IC embedded in a portable terminal detects a charging error and reports occurrence of the error to a CPU. Therefore, the CPU transitions to a sleep mode during a charging operation, thereby saving current consumption. Furthermore, charging efficiency can be improved.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. An apparatus for a charger circuit in a portable terminal, the apparatus comprising:
a charger Integrated Circuit (IC) for, upon detecting insertion of a charging cable, determining whether a charging error occurs by collecting charging-related information, and for outputting a signal for indicating the occurrence of the charging error; and
a Central Processing Unit (CPU) for performing an error control operation upon receiving the signal for indicating the occurrence of the charging error from the charger IC.

2. The apparatus of claim 1, wherein the CPU enters a sleep mode upon detecting the insertion of the charging cable, and wakes up from the sleep mode upon receiving the signal for indicating the occurrence of the charging error.

3. The apparatus of claim 1,
wherein the charging-related information comprises at least one of temperature, current, voltage, and Voltage Feedback (VF) information, and
wherein the charging IC comprises an Analog to Digital Converter (ADC) for measuring at least one of the temperature, the current, and the voltage.

4. The apparatus of claim 3, wherein the charger IC determines whether the charging error occurs according to a comparison result obtained by comparing the measured information and a pre-set threshold.

5. The apparatus of claim 1, wherein the charger IC determines whether the charging error occurs by periodically collecting the charging-related information during the charging operation.

6. The apparatus of claim 1, wherein the charging error comprises at least one of a battery error caused by an unauthorized battery or a battery fault, a full charging error, a temperature error, and an over voltage error.

7. A method of operating a charger circuit in a portable terminal, the method comprising:
detecting insertion of a charging cable;
upon detecting the insertion of the charging cable, determining by a charger Integrated Circuit (IC) whether a charging error occurs by collecting charging-related information;
outputting a signal for indicating the occurrence of the charging error by the charger IC to a Central Processing Unit (CPU); and
performing a control operation depending on a charging error by the CPU.

8. The method of claim 7, further comprising:
allowing the CPU to enter a sleep mode upon detecting the insertion of the charging cable; and
allowing the CPU to wake up from the sleep mode upon receiving the signal for indicating the occurrence of the charging error.

9. The method of claim 7,
wherein the charging-related information comprises at least one of temperature, current, voltage, and Voltage Feedback (VF) information, and
wherein at least one of the temperature, the current, and the voltage is measured by an Analog to Digital Converter (ADC).

10. The method of claim 9, wherein the determining of whether the charging error occurs further comprises determining whether the charging error occurs according to a comparison result obtained by comparing the measured information and a pre-set threshold.

11. The method of claim 7, wherein the charger IC determines whether the charging error occurs by periodically collecting the charging-related information during the charging operation.

12. The method of claim 7, wherein the charging error comprises at least one of a battery error caused by an unauthorized battery or a battery fault, a full charging error, a temperature error, and an over voltage error.
